(19) United States
(12) Patent Application Publication
(10) Pub. No.: US 2019/0257876 A1
(43) Pub. Date: Aug. 22, 2019

(54) SYSTEM AND METHOD FOR DETECTING DEFECTS IN AN ELECTRONIC DEVICE

(71) Applicant: ASM Technology Singapore Pte Ltd, Singapore (SG)

(72) Inventors: Chung Yan LAU, Hong Kong (HK); Chi Wah CHENG, Hong Kong (HK)

(21) Appl. No.: 15/901,403

(22) Filed: Feb. 21, 2018

(51) Int. Cl. G01R 31/265; G01R 31/308

(52) U.S. Cl. CPC G01R 31/2656; G01R 31/308

(57) ABSTRACT

Defects in an electronic device are detected by capturing a first image from a first side of the electronic device, and capturing a second image from a second side of the electronic device which is different from the first side. The first and second images are captured when an inside of the electronic device is illuminated by light rays passed therethrough. If a defect is present in the electronic device, a profile of the defect is determined based on the first and second images and the electronic device is rejected if it is assessed from the profile of the defect that it is of a type for which the electronic device should be rejected.

### FIELD OF THE INVENTION

The invention relates to the inspection of electronic devices, in particular to the inspection of defects in electronic devices.

### BACKGROUND AND PRIOR ART

Defects in electronic devices, such as in wafer level electronic devices, are typically inspected by a high magnification visible light microscope adapted for viewing visible light. In a final packaging process, the electronic devices usually need to undergo visual inspection and checking so as to ensure that the devices are free from damage before packaging. However, if there are defects that are not found on the surfaces of the electronic device but inside the device body, optical apparatus using visible light for inspecting would not be able to locate such defects inside the device body. Moreover, even though blemishes may appear at side surfaces of the electronic devices, it is difficult to distinguish if such blemishes are true defects or just acceptable surface scratches.

To be able to inspect defects that are inside the device body, light in the infrared spectrum may be used for semiconductor materials that are transparent to infrared light in order to detect internal defects in such semiconductor materials. In this case, the infrared light would be able to penetrate into the device body. Such semiconductor materials that are transparent to infrared light may include gallium arsenide, indium phosphide and silicon. In particular, gallium arsenide and indium phosphide can be penetrated by infrared light with a wavelength of about 1064 nm, whereas silicon may be penetrated by infrared light with a wavelength of more than 1400 nm.

In one approach, reflections from inside an electronic device may be imaged by projecting infrared light into the electronic device from a surface thereof, such that a crack would appear as a bright line. For instance, U.S. Pat. No. 8,224,062 entitled “Method and Apparatus for Inspection of Wafer and Semiconductor Device” describes irradiating a backside of a semiconductor chip with an infrared ray to inspect the semiconductor chip based upon the reflected ray. An image is obtained showing cracks formed in the semiconductor chip. In this way, defects such as cracks or foreign marks on the semiconductor chip can be detected.

However, the aforesaid approach can only highlight part of a crack, and the extent of the crack that is highlighted depends on an angle of the cracked surface relative to the incident infrared rays. If the infrared rays cannot be received by an imaging device, then the cracks will appear dark and indistinguishable. Thus, this approach would unreliable if the defect is aligned with the light path, meaning that the real defect cannot be perceived. Another possibility is that the infrared light cannot distinguish if a suspected “defect” in an image is a real defect or merely an acceptable surface scratch, such as saw marks. This will cause a false detection of a defect.

Finally, if there is any interference along the light path, such as a surface scratch, saw marks or the like, the system would not be able to accurately determine whether there is an internal defect.

### SUMMARY OF THE INVENTION

It is thus an object of the invention to seek to provide a system and method for detecting defects in semiconductor materials with greater accuracy as compared with the prior art.

According to a first aspect of the invention, there is provided a method for detecting defects in an electronic device, comprising the steps of: capturing a first image from a first side of the electronic device; capturing a second image from a second side of the electronic device which is different from the first side; wherein the first and second images are captured when an inside of the electronic device is illuminated by light rays passed therethrough; if a defect is present in the electronic device, determining a profile of the defect based on the first and second images; and thereafter rejecting the electronic device if it is assessed from the profile of the defect that it is of a type for which the electronic device should be rejected.

According to a second aspect of the invention, there is provided a method for detecting defects in an electronic device, comprising the steps of: capturing a first image of a first view of the electronic device; capturing a second image of a second view of the electronic device which is different from the first view; wherein the first and second images are captured when an inside of the electronic device is illuminated by light rays passed therethrough, and the first and second views are substantially perpendicular relative to one another; if a defect is present in the electronic device, determining a profile of the defect based on the first and second images; and thereafter rejecting the electronic device if it is assessed from the profile of the defect that it is of a type for which the electronic device should be rejected.

It would be convenient hereinafter to describe the invention in greater detail by reference to the accompanying drawings which illustrate specific preferred embodiments of the invention. The particularity of the drawings and the related description is not to be understood as superseding the generality of the broad identification of the invention as defined by the claims.

### BRIEF DESCRIPTION OF THE DRAWINGS

An exemplary system and method for detecting defects in an electronic device in accordance with the invention will now be described with reference to the accompanying drawings, in which:

FIGS. 1A to 1D illustrate different views of an electronic device illustrating how an internal defect in an electronic device may be detected using the system and method according to the preferred embodiment of the invention;

FIG. 2 is an isometric view of a setup for inspecting an electronic device according to a first preferred embodiment of the invention;

FIG. 3 is an isometric view of a setup for inspecting an electronic device according to a second preferred embodiment of the invention;

FIG. 4 is an isometric view of a setup for inspecting an electronic device according to a third preferred embodiment of the invention;

FIG. 5 is an isometric view of a setup for inspecting an electronic device according to a fourth preferred embodiment of the invention;

FIG. 6 is an isometric view of a setup for inspecting an electronic device according to a fifth preferred embodiment of the invention; and

FIG. 7 is an exemplary decision flowchart for implementing the method according to the preferred embodiment of the invention.

### DETAILED DESCRIPTION OF THE PREFERRED EMBODIMENT OF THE INVENTION

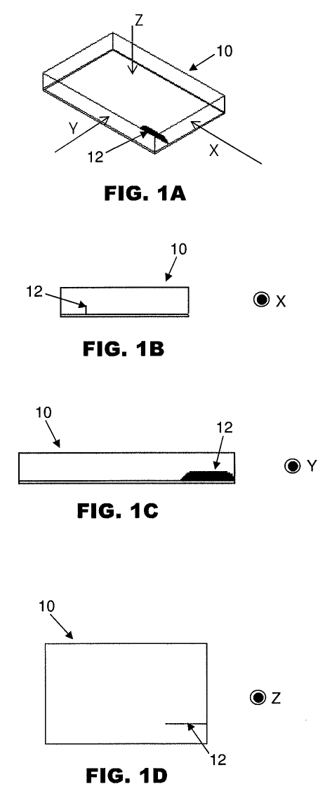

FIGS. 1A to 1D illustrate different views of an electronic device 10 illustrating how an internal defect 12 in an electronic device, such as a crack, may be detected using the system and method according to the preferred embodiment of the invention. In general, FIG. 1A shows the various views from which the electronic device 10 is inspected from the X, Y and Z directions.

FIG. 1B is a view of the electronic device 10 from the X direction or axis of FIG. 1A. From the X direction, the defect 12 is too thin to be detected, and thus may be missed. FIG. 1C is a view of the electronic device 10 from the Y direction or axis of FIG. 1A. From the Y direction, the defect 12 is more apparent, such that the electronic device 10 may be recognized as being defective. Finally, FIG. 1D is a view of the electronic device 10 from the Z direction or axis of FIG. 1A. From the Z direction, the defect 12 is again too thin to be detected, and the defect 12 may also be missed when the electronic device 10 is viewed only in the Z direction.

In summary, by combining the information gleaned from the different views of the electronic device 10, the risk that a defect 12 may be missed or a blemish that unnecessarily results in a rejection is drastically reduced. By obtaining images of a defect 12 from different views, the system is able to profile the defect 12 more accurately, and therefore distinguish whether the defect 12 is one that is acceptable or unacceptable. For instance, if the defect 12 is simply a scratch on the surface of the electronic device 10 and does not extend into the electronic device 10, there is no need to reject the electronic device 10.

It should be appreciated that although the embodiments of the invention described herein relate to capturing images of the electronic device 10 from three different directions such that a more precise profile of the defect 12 may be determined, the principles of the invention are also applicable to capturing images of the electronic device 10 from only two different directions. Although obtaining images of the electronic device 10 from only two directions might not be as precise or detailed as obtaining the same from three directions, the inspection process would nevertheless still be improved as compared to using capturing only an image of the electronic device 10 from one direction. For instance, the advantage of inspecting the electronic device 10 from two directions can be illustrated by a combination of the images shown solely in FIG. 1B and FIG. 1C above.

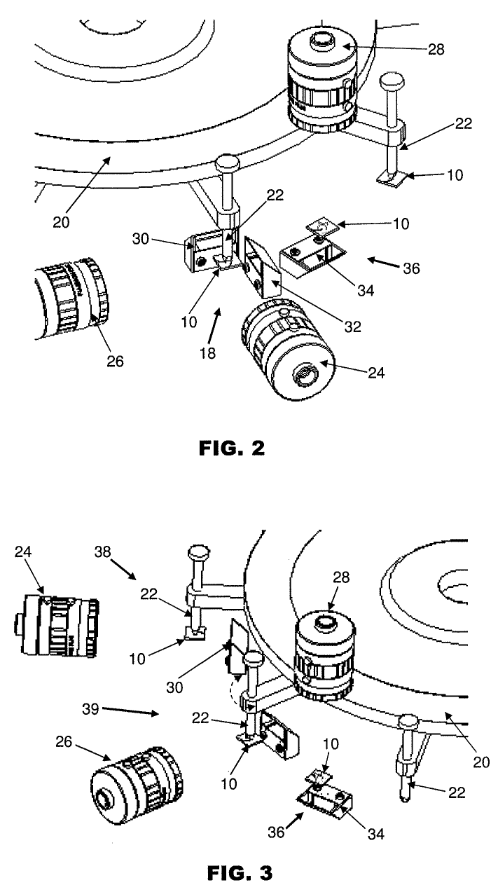

FIG. 2 is an isometric view of a setup for inspecting an electronic device 10 according to a first preferred embodiment of the invention. The system comprises a rotary turret 20, which has a number of pick heads 22 arranged around a perimeter of the rotary turret 20. A position relative to the rotary turret 20 is selected as a first inspection station 18, whereat a first imaging device, which may be in the form of an X infrared camera 24, and a second imaging device, which may be in the form of a Y infrared camera 26, are arranged to view an electronic device 10 that is being held by a pick head 22. The electronic device 10 is transferred by the pick head 22 to one or more focus positions of the respective infrared cameras 24, 26 for inspection at the first inspection station.

An X infrared light source 30 is used to illuminate a first side of the electronic device 10 when it is being inspected by the X infrared camera 24 and a Y infrared light source 32 is used to illuminate a scone side of the electronic device 10 when it is being inspected by the Y infrared camera 26. The first side is different from the second side, and the first and second sides are preferably perpendicular relative to each other. However, it is not necessary that only the first side or the second side is exclusively viewable in each image that is captured.

In both instances, infrared light emanating from the respective infrared light sources 30, 32 pass through the electronic device 10 being held by the pick head before the infrared light reaches and is received by the respective infrared camera 24, 26. A first image from the first side of the electronic device 10 and a second image from the second side of the electronic device are thus captured. For example, any defects 12 in the electronic device 10 will likely appear as a shadow at the respective infrared cameras 24, 26.

After inspecting the first and second sides of the electronic device 10 in the X and Y directions with the X infrared camera 24 and the Y infrared camera 26 respectively, the pick head 22 moves the electronic device 10 to a position of a second inspection station in the form of a down-look station 36. The electronic device 10 is then placed onto the down-look station 36. A third imaging device, which may be in the form of a Z infrared camera 28, is arranged above the down-look station 36 for inspecting a third side of an electronic device 10 that has been placed at the down-look station 36. The third side of the electronic device 10 is different from the first and second sides, and is preferably perpendicular to both the first and second sides.

A Z infrared light source 34 is in turn located underneath the electronic device 10 to illuminate the third side of the electronic device 10 with infrared light when the latter is being inspected, such that infrared light rays pass through the electronic device 10 to illuminate the third side of the electronic device 10 before reaching and being received by the Z infrared camera 28.

With the aforesaid arrangement according to the first preferred embodiment of the invention, it would be appreciated that the electronic device 10 is inspected in the X and Y directions at the inspection station 18, and then inspected in the Z direction at the down-look station 36. If a defect 12 is present in the electronic device 10, an accurate profile of the defect may be determined based on the first, second and third images taken of different sides of the electronic device 10, such as in the X, Y and Z directions respectively.

An advantage is this approach is that, for instance, surface scratches will not show defect patterns from viewing angles that are parallel to the scratched surface, whereas genuine defects will present defect patterns at different angles, so as to be correctly distinguished. Therefore, images of any defect 12 that may be present in the electronic device 10 may be imaged and profiled accurately based on views of the electronic device 10 seen from three different directions, and only defects 12 that are assessed to be of a type that is unacceptable and should be rejected would be rejected by the system.

FIG. 3 is an isometric view of a setup for inspecting an electronic device 10 according to a second preferred embodiment of the invention. The system comprises a rotary turret 20, which has a number of pick heads 22 arranged around a perimeter of the rotary turret 20. There is a first inspection station 38 located relative to the rotary turret 20 where an X infrared camera 24 is arranged to view a first side of an electronic device 10 which is being held by a pick head 22. An X infrared light source 30 is arranged behind the pick head 22 such that the electronic device 10 is positionable between the X infrared light source 30 and the X infrared camera 24. Hence, at least a portion of the infrared light rays emanating from the X infrared light source 30 pass through the electronic device 10 before reaching and being received by the X infrared camera 24.

Further, there is a second inspection station 39 located after the first inspection station 38 where a Y infrared camera 26 is arranged to view a second side of the electronic device 10 which is perpendicular to the first side that was previously inspected by the X infrared camera 24. To achieve this, the pick head 22 may rotate the electronic device 10 by 90° before the electronic device 10 is inspected by the Y infrared camera 26. A Y infrared light source 32 is arranged behind the pick head 22 so that infrared light emanating from the Y infrared light source 32 passes through the electronic device 10 before reaching the Y infrared camera 26.

Subsequently, after inspection of the electronic device 10 by the Y infrared camera 26, the electronic device 10 is placed onto a down-look station 36 for the electronic device 10 to be viewed by a Z infrared camera 28. The Z infrared camera 28 is arranged above the down-look station 36 for inspecting the electronic device 10 that has been placed at the down-look station 36. A Z infrared light source 34 is located underneath the electronic device 10 to illuminate the electronic device 10 with infrared light when the latter is being inspected.

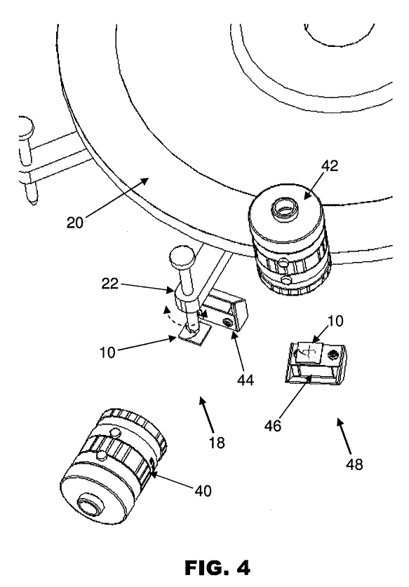

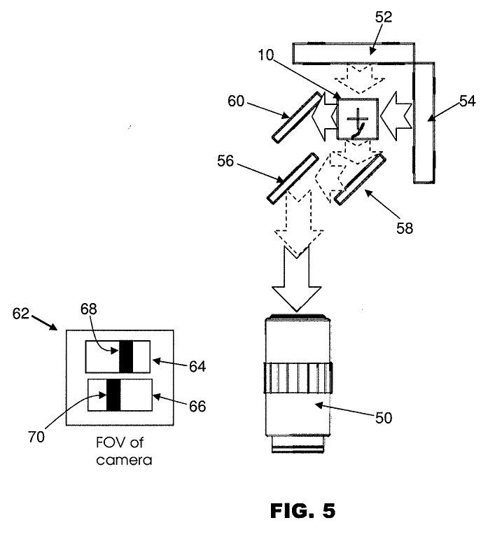

FIG. 4 is an isometric view of a setup for inspecting an electronic device 10 according to a third preferred embodiment of the invention. In this system, a position relative to the rotary turret 20 is selected as an inspection station 18. However, there is only a single XY infrared camera 40 located at the inspection station 18 for viewing the electronic device 10 that is being held by a pick head 22 in both in the X and the Y directions. A single XY infrared light source 44 is arranged behind the pick head 22 so that infrared light emanating from the XY infrared light source 44 passes through the electronic device 10 before reaching the XY infrared camera 40.

Thus, when the electronic device 10 is being held at the inspection station 18 by the pick head 22, the XY infrared camera 40 would view and inspect a first side of the electronic device 10. Thereafter, the pick head 22 would rotate the electronic device 10 by 90° so that a second side of the electronic device 10 which is perpendicular to the first side of the electronic device 10 is viewed by the XY infrared camera 40. During inspection of the second side of the electronic device 10, the electronic device 10 is similarly illuminated by the XY infrared light source 44.

After the electronic device 10 has been inspected in the X and Y directions, the electronic device 10 is placed by the pick head 22 onto a down-look station 46. A Z infrared camera 42 arranged above the down-look station 36 may at this time inspect the electronic device 10 that has been placed at the down-look station 46. A Z infrared light source 34 is located underneath the electronic device 10 to illuminate the electronic device 10 with infrared light when the latter is being inspected.

FIG. 5 is an isometric view of a setup for inspecting an electronic device 10 according to a fourth preferred embodiment of the invention. In this embodiment, a single XY infrared camera 50 is able to inspect an electronic device 10 in the X and Y directions without rotating the electronic device.

To do so, an X infrared light source 52 and a Y infrared light source 54 are arranged to face first and second sides of the electronic device 10 which are perpendicular to each other. Infrared light emanating from the X infrared light source 52 that has passed through the electronic device 10 is reflected by an X mirror 58 towards a beam-splitter or half-mirror 56. Similarly, infrared light emanating from the Y infrared light source 54 that has passed through the electronic device 10 is reflected by a Y mirror 60 towards the half-mirror 56. Infrared light rays from the two respective paths are directed towards the XY infrared camera 50, allowing the XY infrared camera 50 to simultaneously view the electronic device 10 in X and Y directions without having to rotate the electronic device 10.

A field of view 62 of the XY infrared camera 50 would comprise an X image 64 of an X-direction profile 68 of a defect 12, as well as a Y image 66 of a Y-direction profile 70 of the defect 12. Accordingly, images of the defect 12 in the X and Y directions may be obtained simultaneously.

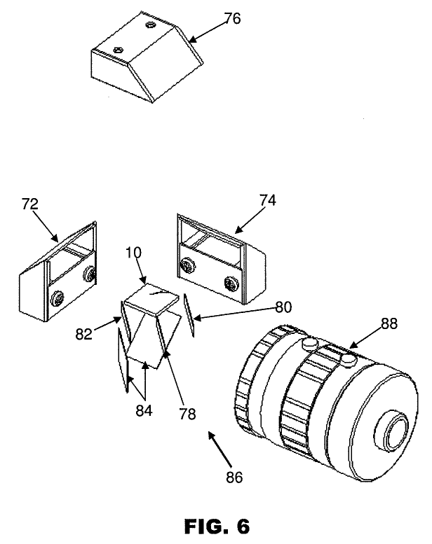

FIG. 6 is an isometric view of a setup for inspecting an electronic device 10 according to a fifth preferred embodiment of the invention. In this system, there is a single XYZ inspection station 86 where it is possible to inspect an electronic device 10 in X, Y and Z directions simultaneously.

An XYZ infrared camera 88 is arranged to inspect the electronic device 10 placed at the XYZ inspection station 86. An X infrared light source 72 and a Y infrared light source 74 are arranged to face first and second sides of the electronic device 10 which are perpendicular to each other. Infrared light emanating from the X infrared light source 72 that has passed through the electronic device 10 is reflected by an X mirror 80 towards a beam-splitter or half-mirror 78. On the other hand, infrared light emanating from the Y infrared light source 74 that has passed through the electronic device 10 is reflected by a Y mirror 82 towards the half-mirror 78. Infrared light rays from the two respective paths are directed towards the XYZ infrared camera 88.

Additionally, a Z infrared light source 76 is arranged above the XYZ inspection station 86 to direct infrared light onto a top surface of the electronic device 10. A pair of Z mirrors 84 located underneath the electronic device 10 directs infrared light which has passed through the electronic device 10 towards the XYZ infrared camera 88.

The aforesaid setup allows the XYZ infrared camera 88 to simultaneously view the electronic device 10 in X, Y and Z directions without having to rotate the electronic device 10 or to move it to different stations. Two or more of the various infrared light sources 72, 74, 76 are preferably in different phases to facilitate the imaging of the various views of the electronic device 10 simultaneously by a single XYZ infrared camera 88.

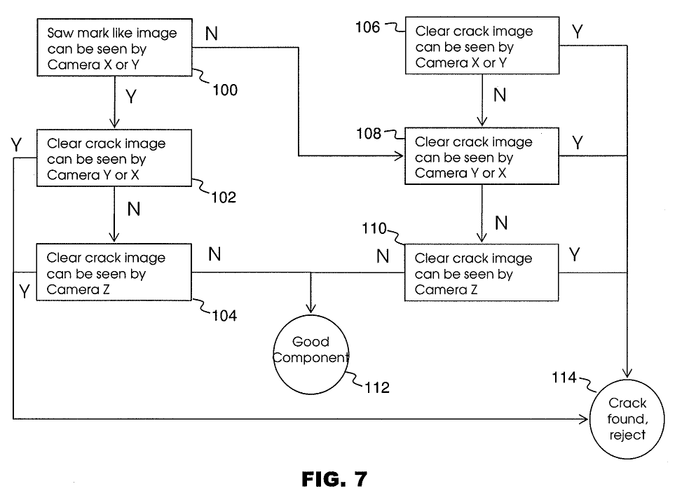

FIG. 7 is an exemplary decision flowchart for implementing the method according to the preferred embodiment of the invention. At step 100, the system first looks for whether a saw mark like image is seen by a camera in the X or Y directions. If so, then at step 102, the system verifies whether a clear crack image can be seen by a camera in the Y or X direction respectively. If not, then at step 104, it is determined whether a crack image can be seen by a camera in the Z direction. If a clear crack image is seen at either step 102 or step 104, the system may conclude that a crack exists.

Alternative, at step 106, even if there is no saw mark like image, it is determined whether a clear crack image can be seen by a camera in the X or Y directions. If not, it is determined at step 108 whether a clear crack image can be seen by a camera in the Y or X directions respectively. If a clear crack image cannot be seen by a camera in either the X or Y directions, it is finally determined at step 110 whether a clear crack image can be seen by a camera in the Z direction. If a clear crack image can be seen by a camera in either the X, Y or Z directions, the system would conclude at step 114 that a crack exists and would reject the electronic device 10.

If no crack images are found by any camera in any of the X, Y or Z directions as outlined above, the system may conclude at step 112 that the electronic device 10 is a good one.

It should be appreciated that clear images revealing possible defects inside electronic devices 10 are obtainable with the system and method according to the preferred embodiments of the inventions disclosed above. This improves the accuracy of finding and assessing possible defects, especially inside wafer-level electronic devices 10. The rate of over-rejection or under-rejection may be correspondingly reduced.

Whilst the respective infrared cameras are arranged in X, Y and Z directions that are perpendicular to one another in the above preferred embodiments, it should be appreciated that the infrared cameras may also be arranged at other angles that are not perpendicular to one another without detracting from the invention. As such, views of the electronic device 10 from various perspectives may be obtained at angles which are more than or less than 90° relative to one another.

The invention described herein is susceptible to variations, modifications and/or additions other than those specifically described and it is to be understood that the invention includes all such variations, modifications and/or additions which fall within the spirit and scope of the above description.

1. Method for detecting defects in an electronic device, comprising the steps of:
capturing a first image from a first side of the electronic device;
capturing a second image from a second side of the electronic device which is different from the first side;
wherein the first and second images are captured when an inside of the electronic device is illuminated by light rays passed therethrough;
if a defect is present in the electronic device, determining a profile of the defect based on the first and second images; and thereafter
rejecting the electronic device if it is assessed from the profile of the defect that it is of a type for which the electronic device should be rejected.

2. Method as claimed in claim 1, further comprising the steps of capturing a third image from a third side of the electronic device which is different from the first and second sides and determining the profile of the defect based on the first, second and third images, wherein the third image is captured when the inside of the electronic device is illuminated by light rays passed therethrough.

3. Method as claimed in claim 2, wherein the third side is perpendicular to the first and second sides.

4. Method as claimed in claim 2, wherein two of the first, second and third images are captured at a first inspection station and one of the images is captured at a second inspection station which is separate from the first inspection station.

5. Method as claimed in claim 4, further comprising the step of rotating the electronic device between the steps of capturing a respective one of the two images captured at the first inspection station.

6. Method as claimed in claim 1, wherein at least one of the first and second images are captured when the electronic device is positioned between a light source and an imaging device.

7. Method as claimed in claim 6, wherein the electronic device is held by a pick head of a rotary turret when it is positioned between the light source and the imaging device.

8. Method as claimed in claim 6, wherein the electronic device is placed onto a down-look station when it is positioned between the light source and the imaging device.

9. Method as claimed in claim 6, wherein at least a portion of light rays emanating from the light source are passed through the electronic device before being received by the imaging device.

10. Method as claimed in claim 1, wherein each of the first and second images is captured at a separate inspection station.

11. Method as claimed in claim 10, further comprising the step of rotating the electronic device between the steps of capturing an image of the electronic device at a respective inspection station.

12. Method as claimed in claim 1, wherein the first and second images are captured at a single inspection station.

13. Method as claimed in claim 12, further comprising first and second light sources for illuminating the electronic device from different sides thereof, and light rays from the first and second light sources that are passed through the electronic device are received by a single imaging device.

14. Method as claimed in claim 13, further comprising first and second mirrors to direct light from the first and second light sources towards the single imaging device.

15. Method as claimed in claim 13, wherein the first and second light sources are in different phases.

16. Method as claimed in claim 1, further comprising a mirror facing a side of the electronic device for capturing the first or second image, the mirror being arranged to reflect light rays emanating from the side of the electronic device towards an imaging device.

17. Method as claimed in claim 16, further comprising a beam splitter through which the light rays reflected from the mirror is passed before reaching the imaging device.

18. Method as claimed in claim 1, wherein the first and second sides are perpendicular to each other.

19. Method as claimed in claim 1, wherein the light rays comprise infrared light rays.

20. Method for detecting defects in an electronic device, comprising the steps of:
capturing a first image of a first view of the electronic device;
capturing a second image of a second view of the electronic device which is different from the first view;
wherein the first and second images are captured when an inside of the electronic device is illuminated by light rays passed therethrough, and the first and second views are substantially perpendicular relative to one another;
if a defect is present in the electronic device, determining a profile of the defect based on the first and second images; and thereafter
rejecting the electronic device if it is assessed from the profile of the defect that it is of a type for which the electronic device should be rejected.
